(19) United States
(12) Patent Application Publication
(10) Pub. No.: US 2020/0066848 A1
(43) Pub. Date: Feb. 27, 2020

(54) GALLIUM NITRIDE TRANSISTOR WITH UNDERFILL ALUMINUM NITRIDE FOR IMPROVED THERMAL AND RF PERFORMANCE

(71) Applicant: Intel Corporation, Santa Clara, CA (US)

(72) Inventors: Han Wui THEN, Portland, OR (US); Sansaptak DASGUPTA, Hillsboro, OR (US); Marko RADOSAVLJEVIC, Portland, OR (US); Paul B. FISCHER, Portland, OR (US)

(21) Appl. No.: 16/074,377

(22) PCT Filed: Apr. 1, 2016
(86) PCT No.: PCT/US2016/025719

§ 371 Date: Jul. 31, 2018

(51) Int. Cl. H01L 29/20; H01L 29/66; H01L 29/778; H01L 29/423

(52) U.S. Cl. CPC H01L 29/2003; H01L 29/4236; H01L 29/7786; H01L 29/66462

(57) ABSTRACT

An apparatus including a transistor device on a substrate including an intrinsic layer including a channel; a source and a drain on opposite sides of the channel; and a diffusion barrier between the intrinsic layer and each of the source and the drain, the diffusion barrier including a conduction band energy that is less than a conduction band energy of the channel and greater than a material of the source and drain. A method including defining an area of an intrinsic layer on a substrate for a channel of a transistor device; forming a diffusion barrier layer in an area defined for a source and a drain; and forming a source on the diffusion barrier layer in the area defined for the source and forming a drain in the area defined for the drain.

### BACKGROUND

### Field

Gallium nitride transistors and circuits.

### Description of Related Art

Gallium nitride (GaN) transistors or circuits employed for power amplification, power conversion and switches typically handle large amounts of power. Such transistors and circuits typically dissipate large amounts of heat that needs to be removed by thermal management. Semiconductor substrates with high thermal conductivity are desirable. In high frequency applications, substrates are required to be simultaneously of high thermal conductivity and high resistivity to prevent significant radio frequency (RF) losses in the substrate. Identifying a suitable substrate present challenges. For example, a silicon on insulator (SOI) substrate has a relatively high resistivity but has relatively poor thermal conductivity. A silicon carbide (SiC) substrate has both a relatively high thermal conductivity and high resistivity, but is generally only available at small sizes such as less than 6 inches (about 15 centimeters) in diameter and at high cost. Low-cost bulk silicon substrates typically have sufficiently good thermal conductivity, but do not offer sufficiently high resistivity without incurring substantial increase in wafer production cost and wafer handling overhead. High resistivity silicon substrates are used to obtain low RF losses but they often present challenges in the fabrication process related to avoidance of wafer breakage during handling.

### BRIEF DESCRIPTION OF THE DRAWINGS

FIG. 1 shows a cross-sectional side view of a substrate including a gallium nitride (GaN) transistor device.

FIG. 2 shows a cross-sectional side view of a portion of a substrate which is a portion of a wafer having a buffer layer on a surface thereof.

FIG. 3 shows the structure of FIG. 2 following the introduction of a hard mask on the buffer layer.

FIG. 4 shows the structure of FIG. 3 following the inversion of the structure and formation of an opening or a trench through the substrate to expose the buffer layer on an opposite side of the substrate.

FIG. 5 shows the structure of FIG. 4 following the forming of an aluminum nitride layer in the trench.

FIG. 6 shows the structure of FIG. 5 following the deposition of a sacrificial material in the trench to fill the remaining volume of the trench.

FIG. 7 shows the structure of FIG. 6 following the inversion of the structure and the continued process on a front side or device side of the structure including removal of the hard mask layer.

FIG. 8 shows the structure of FIG. 7 following the formation of a gallium nitride layer and polarization/charge-inducing layer on a device side of the structure.

FIG. 9 shows the structure of FIG. 8 following a patterning of a sacrificial or dummy gate hard mask and a recession of a gallium nitride layer in junction regions.

FIG. 10 shows the structure of FIG. 9 following a source and drain regrowth process.

FIG. 11 shows the structure of FIG. 10 following a trench isolation structure formation around the device.

FIG. 12 shows the structure of FIG. 11 following the patterning of a sacrificial mask into selected dimensions for a gate electrode and the formation of an interlayer dielectric around the patterned sacrificial mask and on the structure.

FIG. 13 shows the structure of FIG. 12 following a replacement metal gate process.

FIG. 14 shows the structure of FIG. 13 following the formation of trench contact to source and drain.

FIG. 15 shows the structure of FIG. 14 following the thinning of the substrate.

FIG. 16 shows a cross-sectional side view of the substrate of, for example, a low resistivity silicon substrate that is, for example, a portion of a larger structure such as a wafer and a nucleation layer on a surface thereof.

FIG. 17 shows the structure of FIG. 16 following the formation of a hard mask layer on a nucleation layer.

FIG. 18 shows the structure of FIG. 17 following the inversion of the substrate and formation of a trench through the substrate to expose a nucleation layer from a backside of the substrate.

FIG. 19 shows the structure of FIG. 18 following the formation of an aluminum nitride layer in the trench.

FIG. 20 shows the structure of FIG. 19 following the filling of a trench with a sacrificial material.

FIG. 21 shows the structure of FIG. 20 following the inversion of the structure and the continued processing on a front side or device side of the substrate.

FIG. 22 shows a cross-sectional side view of second substrate that is, for example, a silicon substrate and a buffer layer and gallium nitride layer formed on a surface thereof.

FIG. 23 shows the structure of FIG. 22 following the formation of a sacrificial mask and the formation of source and drain recessions or cutouts in a gallium nitride layer.

FIG. 24 shows the structure of FIG. 23 following the formation of a source and a drain.

FIG. 25 shows the structure of FIG. 24 following the formation of a trench isolation structure.

FIG. 26 shows the structure of FIG. 25 following the patterning of the sacrificial mask into a sacrificial gate structure having area dimensions for a gate electrode.

FIG. 27 shows the structure of FIG. 26 following the removal of the sacrificial mask and the formation of a gate stack including a gate dielectric and gate electrode.

FIG. 28 shows the structure of FIG. 27 following the bonding of the structure at a device side to a carrier wafer and the removal of the substrate.

FIG. 29 shows the bonding of the structure of FIG. 28 with the structure of FIG. 21.

FIG. 30 shows the structure of FIG. 29 following a thinning of the substrate.

FIG. 31 shows the structure of FIG. 30 following a removal of the carrier wafer.

FIG. 32 is an interposer implementing one or more embodiments.

FIG. 33 illustrates an embodiment of a computing device.

### DETAILED DESCRIPTION

An apparatus and method including a gallium nitride transistor or circuit block on a substrate with an aluminum nitride (AlN) layer under the transistor or circuit block is described. The presence of an aluminum nitride layer under the transistor or circuit block such as in the substrate itself allows the use of a low resistivity substrate such as a low resistivity silicon substrate while providing high resistivity and high thermal conductivity to the structure.

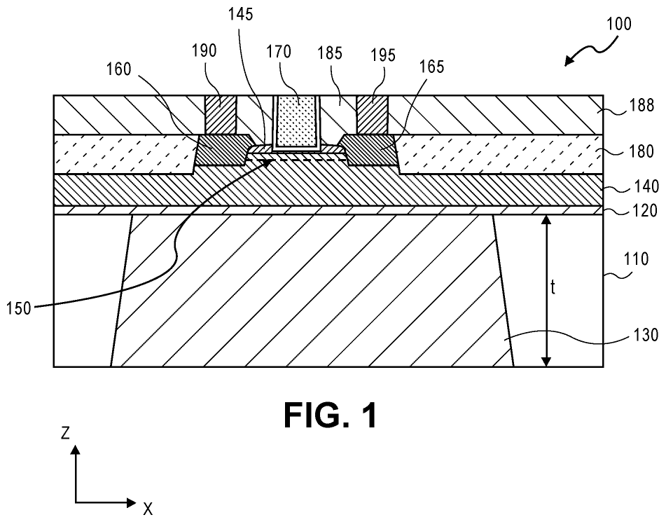

FIG. 1 shows a cross-sectional side view of a substrate including a gallium nitride (GaN) transistor device. Substrate 110 is, in one embodiment, a portion of a larger substrate such as a wafer. In one embodiment, substrate 110 is a low resistivity silicon substrate. A low resistivity silicon substrate in this context refers to a monocrystalline silicon substrate having a bulk resistivity less than 1000 ohms-centimeter (Ω-cm) and more typically on the order of 10 Ω-cm or less.

Disposed on substrate 110 is buffer layer 120 of a material, in one embodiment, to isolate a gallium nitride device or circuit structure from substrate 110. In one embodiment, buffer layer 120 comprises aluminum nitride (AlN). As will be described below, in one process of forming a structure such as structure 100 in FIG. 1, an aluminum nitride buffer layer serves both as a buffer layer to isolate a gallium nitride device or circuit structure from substrate 110 and as a nucleation layer for an aluminum nitride formed in substrate 110.

In one embodiment, a thickness of buffer layer 120 of aluminum nitride is on the order of more than 25 μm. Disposed on buffer layer 120 in structure 100 is a layer of highly resistive gallium nitride. Gallium nitride layer 140 provides a foundation on which a gallium nitride transistor is formed. Representatively, gallium nitride layer 140 may be epitaxially grown to a thickness on the order of more than 1 μm. Following the formation of gallium nitride layer 140, polarization/charge-inducing layer 145 is introduced on gallium nitride layer 140. A polarization/charge-inducing layer is a material that due to the difference in its polarization field compared to that of gallium nitride, attracts electrons toward the interface between gallium nitride layer 140 and polarization/charge-inducing layer 145. This concentration of electrons is referred to as a two-dimensional electron gap (2DEG). In one embodiment, a material for polarization/charge-inducing layer 145 is an alloy of group III elements and nitrogen. Examples include, but are not limited to, aluminum nitride (AlN), aluminum indium nitride (AlInN) and aluminum gallium nitride (AlGaN) where the nitrogen is present at 50 percent of the alloy composition.

FIG. 1 shows gallium nitride transistor including source 160 and drain 165 separated from one another with a gate stack on gallium nitride layer 140 and channel or depletion region 150 in gallium nitride layer 140 separating source 160 and drain 165. In one embodiment, a material for source 160 and drain 165 is an n-type material such as an alloy of a group III-V compound material and nitrogen. An example includes but is not limited to indium gallium nitride (InGaN) formed by an epitaxial deposition process. Source 160 and drain 165 are surrounded by dielectric layer 180 (a trench isolation) of, for example, silicon dioxide or a material having a dielectric constant less than silicon dioxide (a low-k material). Gate stack 170 includes gate dielectric and gate electrode. Gate stack 170 is disposed on a gate dielectric of, for example, silicon dioxide or a high-k material or a combination of silicon dioxide and a high-k material. A material for gate stack 170 is a metal material such as but not limited to tantalum nitride or a silicide.

FIG. 1 shows dielectric spacers 185 of, for example, silicon dioxide or a low-k material formed around gate electrode 170 and the structure disposed in interlayer dielectric 188 of, for example, silicon dioxide or a low-k dielectric material. FIG. 1 also shows trench contact 190 through interlayer dielectric layer 188 to source 160 and trench contact 195 through interlayer dielectric layer 188 to drain 165.

Formed in substrate 110 of structure 100 of FIG. 1 is aluminum nitride layer 130. In one embodiment, aluminum nitride layer 130 is formed by, for example, an epitaxial growth process to a thickness on the order of a thickness of a thinned substrate. Representative thicknesses include a thickness in a z-direction of 50 microns (μm) to 100 μm. As illustrated, aluminum nitride layer 130 does not consume the entire area of substrate 110. Instead, in one embodiment, length and width dimensions of aluminum nitride layer 130 (x-dimension and y-dimension, respectively) are defined to enclose a footprint of the structure or circuit to which the aluminum nitride is supporting. In this case, the aluminum nitride layer is providing resistivity and thermal conductivity support to a transistor structure and has a representative length and width dimension on the order of more than 100 μm.

The inclusion of aluminum nitride layer 130 in substrate 110 provides a number of advantages. First, the aluminum nitride material acts a good insulator to increase a resistivity of the substrate for low radio frequency (RF) loss. The aluminum nitride also has better thermal conductivity (285 Watts/meter/Kelvin (W/m/K)) than silicon (149 W/m/K). Where aluminum nitride layer 130 is introduced by an underfill process as described below, growing it from a buffer layer (buffer layer 120) of aluminum nitride allows the buffer layer to serve as a nucleation layer. Finally, selected placement of an aluminum nitride layer or layers under device structures such as described above and/or transmission line will tend to reduce RF losses and improve thermal performance.

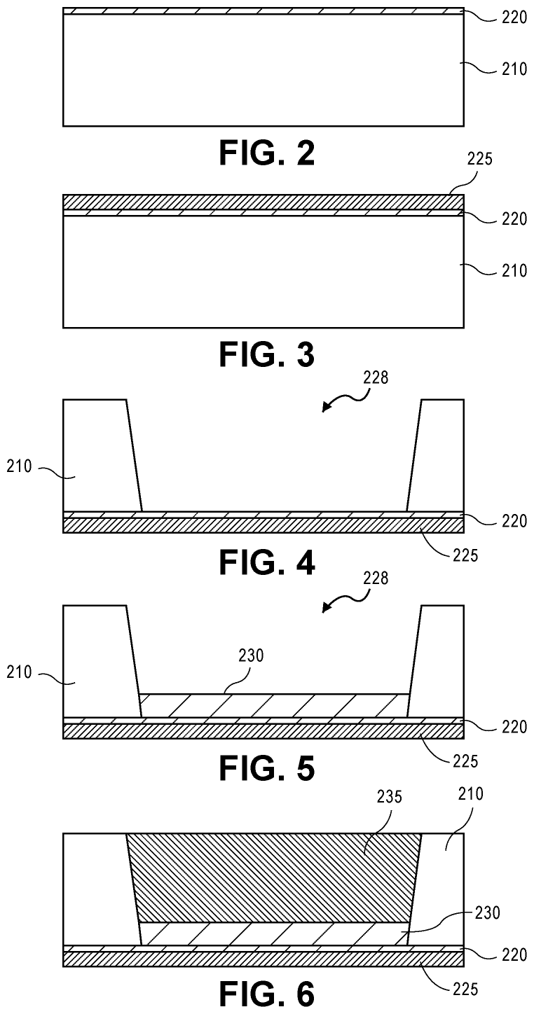

FIGS. 2-15 describe an embodiment of a method of forming the structure of FIG. 1 including a gallium nitride transistor and an aluminum nitride layer in the substrate on which the transistor is formed. Referring to FIG. 2, FIG. 2 shows a cross-sectional side view of a portion of a substrate which is, for example, a portion of a wafer. In one embodiment, substrate 210 is a low resistivity monocrystalline silicon substrate. Disposed on a surface of substrate 210 (a superior surface) is buffer layer 220. In one embodiment, buffer layer 220 is an aluminum nitride material process having a thickness on the order of more than 100 nm. In one embodiment, buffer layer 220 is formed by a metal organic chemical vapor deposition (MOCVD) process.

FIG. 3 shows the structure of FIG. 2 following the introduction of hard mask 225 on buffer layer 220. Hard mask layer 225 is, for example, a silicon nitride material deposited by chemical vapor deposition (CVD) to a thickness to protect buffer layer 220 in subsequent processing of an opposite side of substrate 210.

FIG. 4 shows the structure of FIG. 3 following the inversion of the structure and formation of opening or trench 228 through substrate 210 to expose buffer layer 220 on an opposite side of the substrate. In one embodiment, trench 228 may be formed by a masking and etch process. Representatively, a masking material is deposited on the backside substrate 210 and an area(s) defined for an underfill aluminum nitride layer is exposed. The exposed area(s) of substrate 210 are then etched to form trench 228. A silicon substrate may be etched using a wet or dry etchant. A representative etchant is, for example, potassium hydroxide (KOH) or tetramethylammonium hydroxide (TMAH).

FIG. 5 shows the structure of FIG. 4 following the forming of aluminum nitride layer 230 in trench 228. Aluminum nitride 230 may be formed, for example, by an epitaxial growth process. In one embodiment, aluminum nitride layer 230 is sufficiently thick to match a thickness of substrate 210 following a substrate thinning operation as described below. A representative thickness is on the order of 50 microns to 100 microns for a thinned substrate.

FIG. 6 shows the structure of FIG. 5 following the deposition of sacrificial material 235 in trench 228 to fill the remaining volume of the trench. In one embodiment, sacrificial material 235 is an oxide introduced by a deposition process.

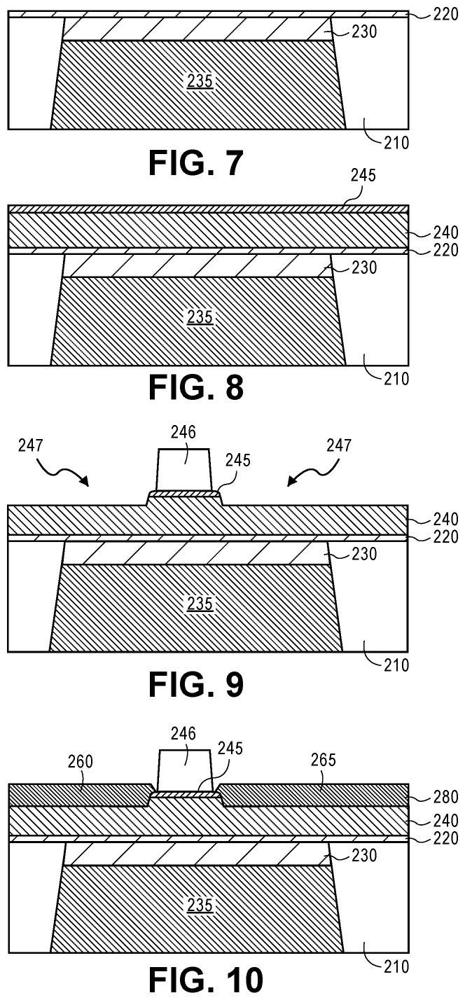

FIG. 7 shows the structure of FIG. 6 following the inversion of the structure and the continued process on a front side of the structure. Specifically, FIG. 7 shows the structure of FIG. 6 following a removal of hard mask 225 by, for example, an etch process.

FIG. 8 shows the structure of FIG. 7 following the formation of a gallium nitride layer and polarization layer. FIG. 8 shows gallium nitride layer 240 introduced by, for example, an epitaxial growth process, formed to a thickness on the order of more than 1 μm. Disposed on a surface of gallium nitride layer 240 (a superior surface as viewed) is polarization layer 245. In one embodiment, polarization layer 245 is an alloy of a group III element or elements and nitrogen. Examples include, but are not limited to, AlN, AlInN and AlGaN, where the nitrogen is 50 percent of the alloy composition.

FIG. 9 shows the structure of FIG. 8 following a patterning of a sacrificial or dummy gate hard mask and a recession of gallium nitride layer 240 in junction regions. More specifically, FIG. 9 shows sacrificial mask 246 of, for example, a silicon nitride material patterned to have area dimensions approximating a gate electrode and sidewall spacers disposed in a targeted position for a gate stack/sidewall spacers and overlying polarization layer 245 and gallium nitride layer 240. On opposing sides of sacrificial mask 246 are source and drain regions. FIG. 9 shows recessions 247 where polarization layer 245 and a portion of gallium nitride layer 240 have been removed in such areas designated for a source and drain, respectively.

FIG. 10 shows the structure of FIG. 9 following a source and drain regrowth process. In one embodiment, source 260 and drain 265 are an alloy of group III-V material with nitrogen such as, but not limited to, InGaN formed by an epitaxial growth process in areas 247.

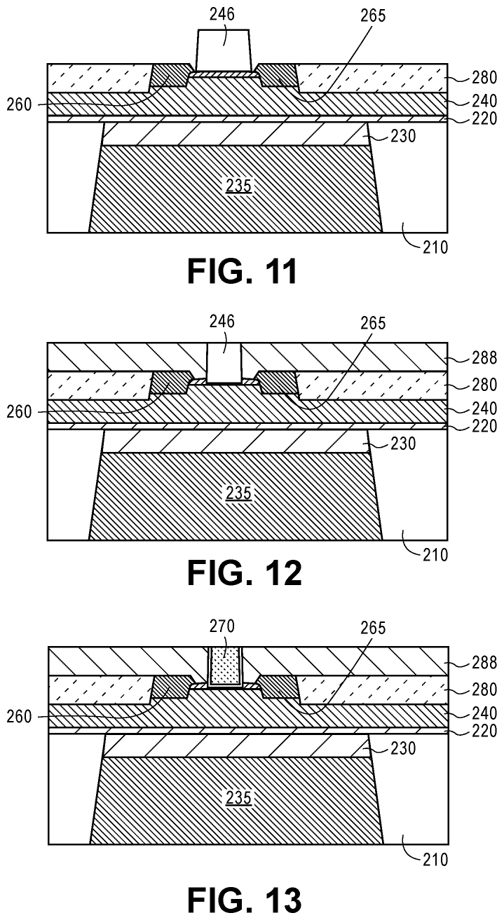

FIG. 11 shows the structure of FIG. 10 following trench isolation. Specifically, FIG. 11 shows trench isolation structure 280 adjacent source 260 and drain 265 and surrounding the transistor device. In one embodiment, trench isolation structure 280 is a dielectric material such as silicon dioxide or low-k material.

FIG. 12 shows the structure of FIG. 11 following the patterning of sacrificial mask 246 into selected dimensions for a gate electrode and the formation of an interlayer dielectric around the patterned sacrificial mask 246 and on the structure. Interlayer dielectric 288 is, for example, a silicon dioxide or a low-k dielectric material.

FIG. 13 shows the structure of FIG. 12 following a replacement metal gate process. In this process, sacrificial mask 246 is removed and polarization layer under sacrificial mask 246 is removed via an etch and the introduction of a gate dielectric and a gate electrode as a gate stack. A suitable material for a gate dielectric is, for example, silicon dioxide or a high-k dielectric material or a mixture of silicon dioxide and a high-k material. A suitable material for gate electrode 270 is, for example, a metal such as tantalum nitride or a silicide.

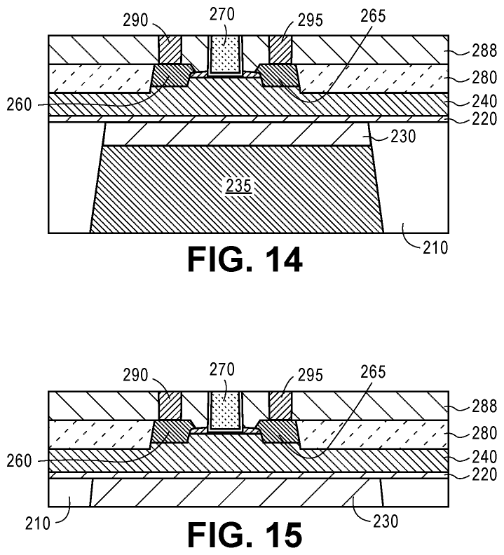

FIG. 14 shows the structure of FIG. 13 following the formation of trench contact to source 260 and drain 265. In one embodiment, openings to the source and drain through interlayer dielectric layer 288 may be formed by a mask and etch process and followed by deposition of a contact material to form trench contact 290 to source 260 and trench contact 295 to drain 265. A suitable material for trench contact 290 and trench contact 295 is, for example, tungsten.

FIG. 15 shows the structure of FIG. 14 following the thinning of substrate 210. In one embodiment, substrate 210 is thinned from its backside to a thickness of aluminum nitride layer 230 thus exposing aluminum nitride layer 230. Substrate thinning may be performed by, for example, a polishing process. The structure in FIG. 15 is similar to that of FIG. 1 described above.

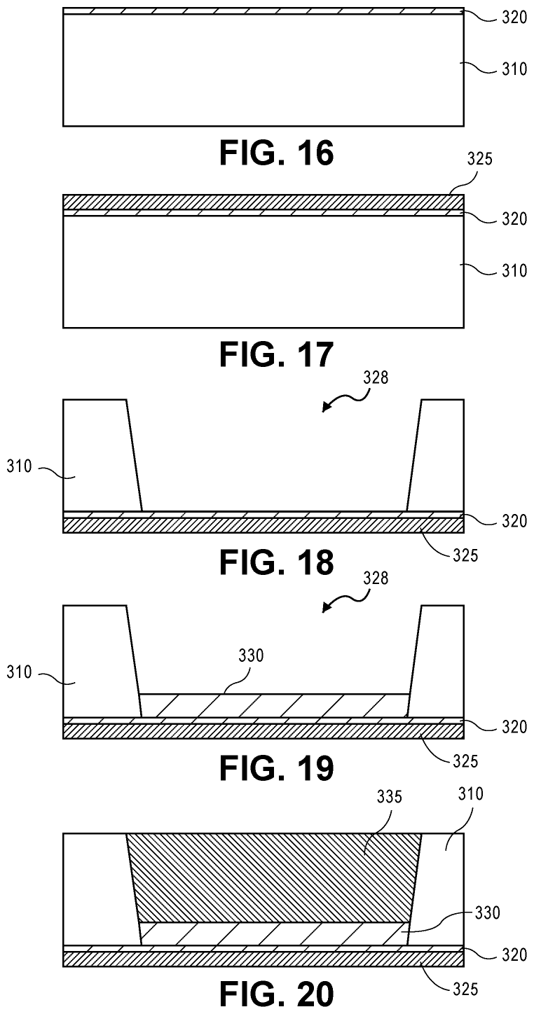

FIGS. 16-29 show a second embodiment of a process flow for forming a gallium nitride transistor or circuit with an aluminum nitride layer under the transistor or circuit. Referring to FIG. 16, the figure shows substrate 310 of, for example, a low resistivity silicon substrate that is, for example, a portion of a larger structure such as a wafer. Overlying a surface of substrate 310 is nucleation layer 320 of, for example, an aluminum nitride layer. A representative thickness of nucleation layer 320 is on the order of more than 100 nm.

FIG. 17 shows the structure of FIG. 16 following the formation of a hard mask layer on nucleation layer 320. In one embodiment, hard mask layer 325 is, for example, a silicon nitride material.

FIG. 18 shows the structure of FIG. 17 following the inversion of the substrate and formation of a trench through the substrate to expose nucleation layer 320 from a backside of the substrate. FIG. 18 shows trench 328 formed through the substrate and nucleation layer 320 exposed on the backside of the substrate. In one embodiment, the trench has dimensions suitable to enclose a footprint of a transistor or circuit device to be formed on or attached to substrate 310.

FIG. 19 shows the structure of FIG. 18 following the formation of aluminum nitride layer 330. In one embodiment, aluminum nitride layer 330 is formed by, for example, an epitaxial growth process to a thickness on the order of 50-100 microns.

FIG. 20 shows the structure of FIG. 19 following the filling of trench 328 with a sacrificial material. Sacrificial material 335 is, for example, an oxide formed by a deposition process.

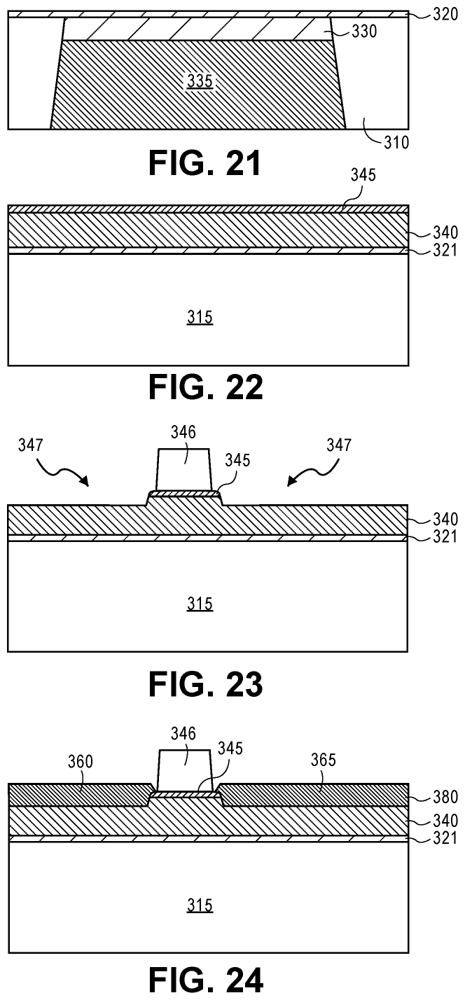

FIG. 21 shows the structure of FIG. 20 following the inversion of the structure and the continued processing on a front side or device side of the substrate. FIG. 21 specifically shows the structure following a removal of hard mask layer 325. Such hard mask layer may be removed by, for example, an etch process.

FIG. 22 shows second substrate 315 that is, for example, a silicon substrate separate from substrate 310. Second substrate 315 has formed on a surface thereof buffer layer 321 of, for example, aluminum nitride material. Bufffer layer 321 serves, in one embodiment to isolate a subsequent gallium nitride layer from the substrate material (e.g., silicon). Buffer layer 321 may be formed by an epitaxial growth process and has a representative thickness on the order of more than 100 nm. Disposed on buffer layer 321 is gallium nitride layer 340 also introduced by, for example, an epitaxial growth process. Gallium nitride layer 340 has a thickness on the order of more than 1 μm. Disposed on gallium nitride layer 340 is polarization layer 345. Suitable materials for polarization layer 345 include alloy in group III elements and nitrogen (e.g., AN, AlInN, AlGaN). Polarization layer 345 may be formed by an epitaxial growth process.

FIG. 23 shows the structure of FIG. 22 following the formation of a sacrificial mask and the formation of source and drain recessions or cutouts in the gallium nitride layer and recessions for a source and drain, respectively, adjacent opposite sides of the sacrificial mask.

FIG. 24 shows the structure of FIG. 23 following the formation of a source and a drain.

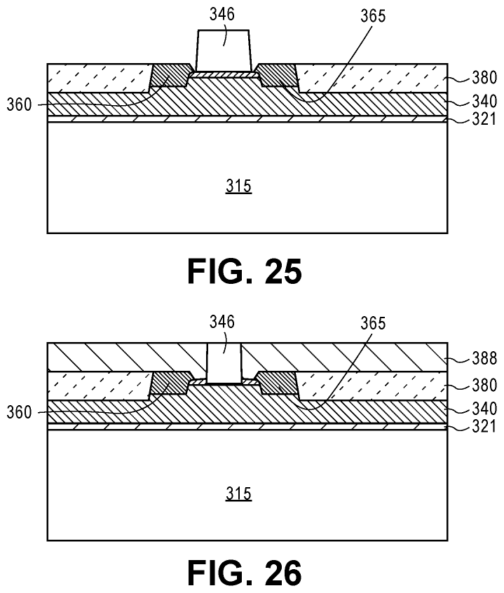

FIG. 25 shows the structure of FIG. 24 following the formation of a trench isolation structure.

FIG. 26 shows the structure of FIG. 25 following the patterning of the sacrificial mask into a sacrificial gate structure having area dimensions for a gate electrode and following the formation of an interlayer dielectric layer.

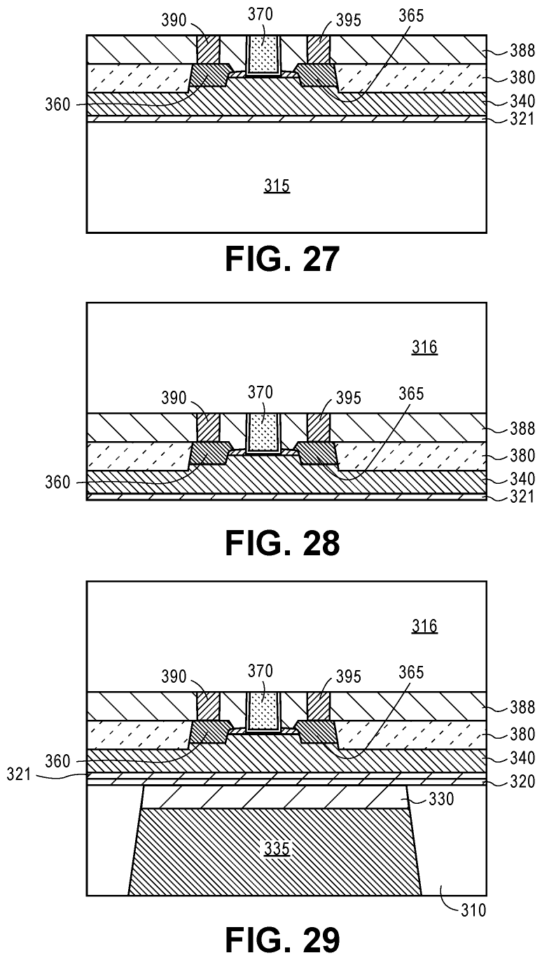

FIG. 27 shows the structure of FIG. 26 following the removal of the sacrificial mask and the formation of a gate stack including a gate dielectric and gate electrode. Gate electrode 370 is, for example, a metal such as a trench contact through interlayer dielectric layer to the source and a trench contact to the drain.

FIG. 28 shows the structure of FIG. 27 following the bonding of the structure at a device side to a carrier wafer and the removal of substrate 315.

FIG. 29 shows the bonding of the structure of FIG. 28 with the structure of FIG. 21.

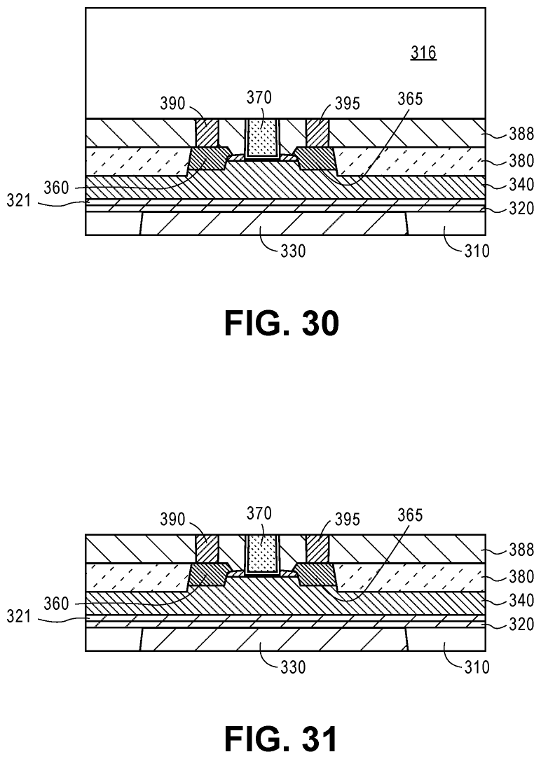

FIG. 30 shows the structure of FIG. 29 following a thinning of the substrate of the structure of FIG. 21.

FIG. 31 shows the structure of FIG. 30 following a removal of the carrier.

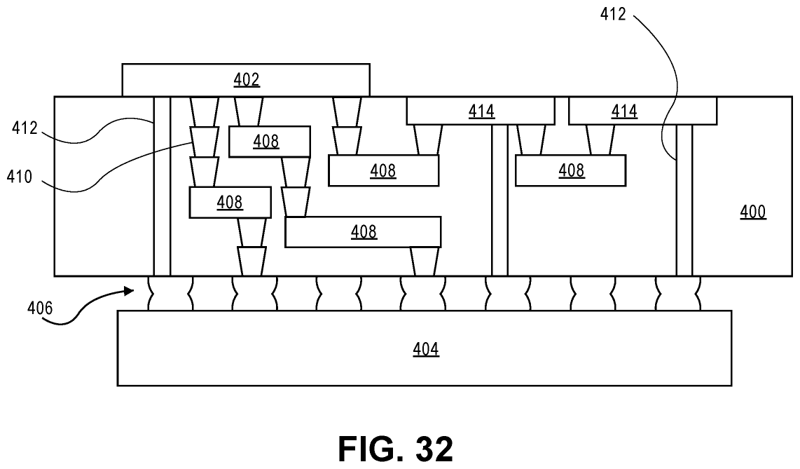

FIG. 32 illustrates interposer 400 that includes one or more embodiments. Interposer 400 is an intervening substrate used to bridge a first substrate 402 to second substrate 404. First substrate 402 may be, for instance, an integrated circuit die. Second substrate 404 may be, for instance, a memory module, a computer motherboard, or another integrated circuit die. Generally, the purpose of interposer 400 is to spread a connection to a wider pitch or to reroute a connection to a different connection. For example, interposer 400 may couple an integrated circuit die to ball grid array (BGA) 406 that can subsequently be coupled to second substrate 404. In some embodiments, first and second substrates 402/404 are attached to opposing sides of interposer 400. In other embodiments, first and second substrates 402/404 are attached to the same side of interposer 400. In further embodiments, three or more substrates are interconnected by way of interposer 400.

Interposer 400 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 408 and vias 410, including but not limited to through-silicon vias (TSVs) 412. Interposer 400 may further include embedded devices 414, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on interposer 400 including GaN transistors and circuits formed according to embodiments described herein.

In accordance with embodiments, apparatuses or processes disclosed herein may be used in the fabrication of interposer 400.

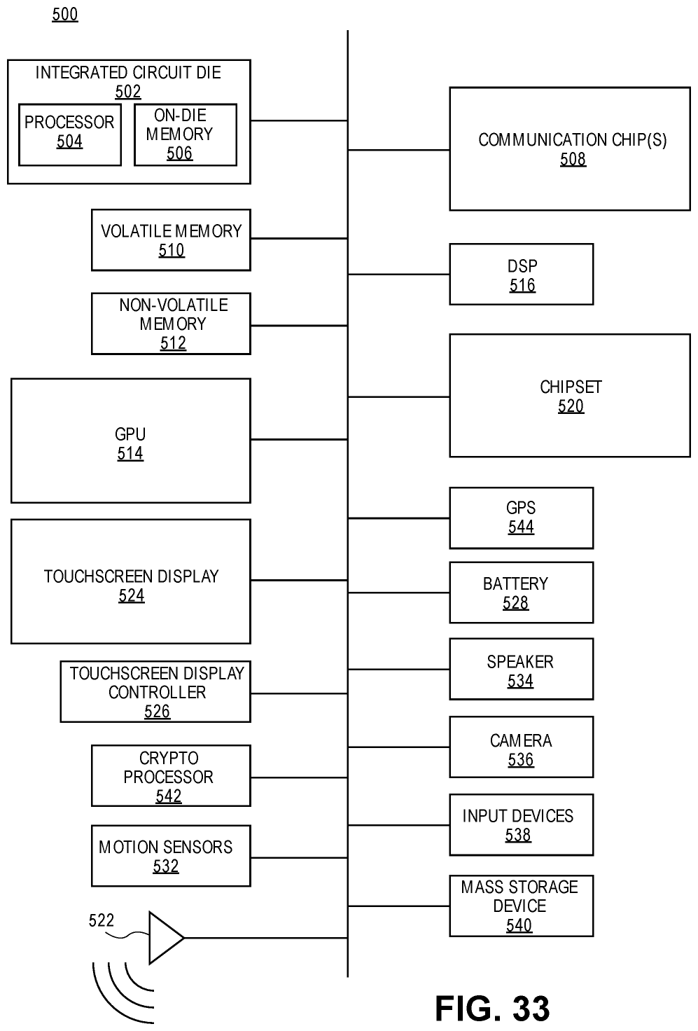

FIG. 33 illustrates computing device 500 in accordance with one embodiment. Computing device 500 may include a number of components. In one embodiment, these components are attached to one or more motherboards. In an alternate embodiment, these components are fabricated onto a single system-on-a-chip (SoC) die rather than a motherboard. The components in computing device 500 include, but are not limited to, integrated circuit die 502 and at least one communication chip 508. In some implementations communication chip 508 is fabricated as part of integrated circuit die 502. Integrated circuit die 502 may include CPU 504 as well as on-die memory 506, often used as cache memory, that can be provided by technologies such as embedded DRAM (eDRAM) or spin-transfer torque memory (STTM or STTM-RAM).

Computing device 500 may include other components that may or may not be physically and electrically connected to the motherboard or fabricated within an SoC die. These other components include, but are not limited to, volatile memory 510 (e.g., DRAM), non-volatile memory 512 (e.g., ROM or flash memory), graphics processing unit 514 (GPU), digital signal processor 516, crypto processor 542 (a specialized processor that executes cryptographic algorithms within hardware), chipset 520, antenna 522, display or a touchscreen display 524, touchscreen controller 526, battery 528 or other power source, a power amplifier (not shown), global positioning system (GPS) device 544, compass 530, motion coprocessor or sensors 532 (that may include an accelerometer, a gyroscope, and a compass), speaker 534, camera 536, user input devices 538 (such as a keyboard, mouse, stylus, and touchpad), and mass storage device 540 (such as hard disk drive, compact disk (CD), digital versatile disk (DVD), and so forth).

Communications chip 508 enables wireless communications for the transfer of data to and from computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 508 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 500 may include a plurality of communication chips 508. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

Processor 504 of computing device 500 includes one or more devices, such as GaN transistors or circuits, that are formed in accordance with embodiments described herein. The term “processor” may refer to any device or portion of a device that processes electronic data from registers and/or memory to transform that electronic data into other electronic data that may be stored in registers and/or memory.

Communication chip 508 may also include one or more devices, such as GaN transistors or circuits, that are formed in accordance with embodiments described herein.

In further embodiments, another component housed within computing device 500 may contain one or more devices, such as GaN transistors or circuits, that are formed in accordance with implementations described herein.

In various embodiments, computing device 500 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 500 may be any other electronic device that processes data.

### EXAMPLES

Example 1 is an apparatus including a transistor device including a channel including gallium nitride disposed on a substrate; a buffer layer disposed on the substrate between the channel and the substrate; and an aluminum nitride layer, wherein the buffer layer is disposed on the aluminum nitride layer.

In Example 2, the aluminum nitride layer of the apparatus of Example 1 is disposed in the substrate.

In Example 3, the substrate of the apparatus of Example 1 or 2 includes silicon.

In Example 4, the substrate of the apparatus of any of Examples 1-3 includes low resistivity silicon.

In Example 5, the buffer layer of the apparatus of any of Examples 1-4 includes aluminum nitride.

In Example 6, an area of the aluminum nitride layer of the apparatus of any of Examples 1-5 includes dimensions that include a footprint of the transistor.

In Example 7, the aluminum nitride layer of the apparatus of any of Examples 1-6 includes a thickness of the substrate.

Example 8 is a method including forming buffer layer on a first side of a substrate; forming a transistor device including a channel including gallium nitride on the buffer layer; and forming a aluminum nitride layer on a second side of the substrate.

In Example 9, forming the aluminum nitride layer in Example 8 includes forming a trench in the second side of the substrate to a depth that exposes the buffer layer; and forming the aluminum nitride layer in the trench.

In Example 10, forming a trench in Example 9 includes forming the trench including an area including dimensions that include a footprint of the transistor.

In Example 11, after forming the aluminum nitride layer in the trench in Example 9 or 10, thinning the substrate to a thickness of the aluminum nitride layer.

In Example 12, forming the buffer layer in any of Examples 8-11 precedes forming the transistor device.

In Example 13, forming the transistor device in Example 8 includes forming the transistor device on a first substrate and forming the aluminum nitride layer includes forming the aluminum nitride layer on a second substrate and the method further includes coupling the substrates together.

In Example 14, after coupling the first and second substrates together, the method of Example 13 includes removing the first substrate.

In Example 15, prior to forming the transistor device on the first substrate, the method of Example 13 includes forming the buffer layer on the first substrate.

In Example 16, the forming the aluminum nitride layer on the second substrate in any of Examples 13-15 includes forming a nucleation layer including aluminum nitride on a first side of the second substrate; and forming a trench in a second side of the second substrate to a depth that exposes the nucleation layer; and forming the aluminum nitride layer in the trench.

Example 17 is an apparatus including a transistor device including a channel including gallium nitride disposed on a silicon substrate; an aluminum nitride layer disposed in the substrate; and a buffer layer disposed between the channel and the aluminum nitride layer.

In Example 18, the aluminum nitride layer of the apparatus of Example 17 includes a thickness of the substrate.

In Example 19, an area of the aluminum nitride layer of the apparatus of Example 17 includes dimensions that include a footprint of the transistor.

In Example 20, the buffer layer of the apparatus of Example 17 includes aluminum nitride.

The above description of illustrated implementations, including what is described in the Abstract, is not intended to be exhaustive or to limit the invention to the precise forms disclosed. While specific implementations of, and examples for, the invention are described herein for illustrative purposes, various equivalent modifications are possible within the scope, as those skilled in the relevant art will recognize.

These modifications may be made in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
a transistor device comprising a channel comprising gallium nitride disposed on a substrate;
a buffer layer disposed on the substrate between the channel and the substrate; and
an aluminum nitride layer, wherein the buffer layer is disposed on the aluminum nitride layer.

2. The apparatus of claim 1, wherein the aluminum nitride layer is disposed in the substrate.

3. The apparatus of claim 1, wherein the substrate comprises silicon.

4. The apparatus of claim 1, wherein the substrate comprises low resistivity silicon.

5. The apparatus of claim 1, wherein the buffer layer comprises aluminum nitride.

6. The apparatus of claim 1, wherein an area of the aluminum nitride layer comprises dimensions that comprise a footprint of the transistor.

7. The apparatus of claim 1, wherein the aluminum nitride layer comprises a thickness of the substrate.

8. A method comprising:
forming buffer layer on a first side of a substrate;
forming a transistor device comprising a channel comprising gallium nitride on the buffer layer; and
forming a aluminum nitride layer on a second side of the substrate.

9. The method of claim 8, wherein forming the aluminum nitride layer comprises:
forming a trench in the second side of the substrate to a depth that exposes the buffer layer; and
forming the aluminum nitride layer in the trench.

10. The method of claim 9, wherein forming a trench comprises forming the trench comprising an area comprising dimensions that comprise a footprint of the transistor.

11. The method of claim 9, wherein after forming the aluminum nitride layer in the trench, thinning the substrate to a thickness of the aluminum nitride layer.

12. The method of claim 8, wherein forming the buffer layer precedes forming the transistor device.

13. The method of claim 8, wherein forming the transistor device comprises forming the transistor device on a first substrate and forming the aluminum nitride layer comprises forming the aluminum nitride layer on a second substrate and the method further comprises coupling the substrates together.

14. The method of claim 13, wherein after coupling the first and second substrates together, the method comprises removing the first substrate.

15. The method of claim 13, wherein prior to forming the transistor device on the first substrate, the method comprises forming the buffer layer on the first substrate.

16. The method of claim 13, wherein the forming the aluminum nitride layer on the second substrate comprises:
forming a nucleation layer comprising aluminum nitride on a first side of the second substrate; and
forming a trench in a second side of the second substrate to a depth that exposes the nucleation layer; and
forming the aluminum nitride layer in the trench.

17. An apparatus comprising:
a transistor device comprising a channel comprising gallium nitride disposed on a silicon substrate;
an aluminum nitride layer disposed in the substrate; and.
a buffer layer disposed between the channel and the aluminum nitride layer.

18. The apparatus of claim 17, wherein the aluminum nitride layer comprises a thickness of the substrate.

19. The apparatus of claim 17, wherein an area of the aluminum nitride layer comprises dimensions that comprise a footprint of the transistor.

20. The apparatus of claim 17, wherein the buffer layer comprises aluminum nitride.
